(19) United States
(12) Patent Application Publication
(10) Pub. No.: US 2012/0017980 A1
(43) Pub. Date: Jan. 26, 2012

(54) PHOTOVOLTAIC PANEL AND METHOD OF MANUFACTURING THE SAME

(75) Inventor: Wing-Yan LAI, Hong Kong (HK)

(73) Assignee: Du Pont Apollo Limited, Hong Kong (HK)

(21) Appl. No.: 13/185,516

(22) Filed: Jul. 19, 2011

Related U.S. Application Data
(60) Provisional application No. 61/366,162, filed on Jul. 21, 2010.

(51) Int. Cl. H01L 31/0203; H01L 31/18; H01L 31/0216

(52) U.S. Cl. 136/256; 136/259; 156/60

(57) ABSTRACT

Disclosed herein are a photovoltaic panel and a method of manufacturing the same. The panel includes a front substrate, a photovoltaic cell on the front substrate, a moisture absorbing layer covering the cell to protect the cell from moisture intrusion, a back substrate on the moisture absorbing layer, and a sealant between the substrates. The method includes the steps of forming the photovoltaic cell on the front substrate, applying the moisture absorbing layer covering the cell, applying the sealant at or near the edges of the front substrate, and securing the back substrate to the front substrate.

### RELATED APPLICATIONS

This application claims priority to U.S. Provisional Application Ser. No. 61/366,162, filed Jul. 21, 2010, which is herein incorporated by reference.

### BACKGROUND

1. Technical Field The present disclosure relates to an energy conversion device. More particularly, the present disclosure relates to a photovoltaic panel and a method of manufacturing the photovoltaic panel.

2. Description of Related Art

Photovoltaic (PV) devices convert light energy, particularly sunlight, into electrical energy, without producing any greenhouse gases during the conversion process, therefore may realize a green energy environment. The electrical energy generated by the photovoltaic devices can be used for all kinds of applications as those achieved by batteries or existing power generators. Recently, along with the progresses and developments of photovoltaic technology, the cost of the PV devices takes a significant price drop thereby rendering PV devices more affordable and more popular in the consumer market. For example, the PV devices can now be found on the residence rooftops and the external walls of buildings, as well as in varies electronic products such as mobile phones, personal digital assistants, digital watches, and laptops.

Generally, a PV device includes a PV cell of semiconductor materials disposed on a front substrate of the device. In order to protect the PV cell, a polymer layer, such as a layer of ethyl vinyl acetate (EVA), is placed on the PV cell. However, while the. PV device is used in an outdoor environment, to maximize its exposure to the sunlight, the moisture from the environment in the form of rain, fog, or even snow becomes a major stimulant that causes EVA delamination, metal oxidation, corrosion and other quality problems. The moisture intrudes into the PV cell through the lateral sides and the back substrate of the PV device, especially when the back substrate is in the form of a polymer back sheet. The moisture gradually penetrates through the EVA and/or the back sheet for a certain time period and eventually gets to contact with the PV cell, which ultimately leads to serious power degradation of the PV is device.

It is therefore an important issue for the manufacturers to improve the resistance of the PV device against moisture.

### SUMMARY

A photovoltaic panel and a method of manufacturing the photovoltaic panel are provided in the disclosure to solve the problems caused by the moisture intrusion to the photovoltaic cell.

According to one aspect of the disclosure, a photovoltaic panel is provided. The photovoltaic panel includes a front substrate, a photovoltaic cell, a moisture absorbing layer, a back substrate, and a sealant. The photovoltaic cell is disposed on the front substrate. The moisture absorbing layer covers the photovoltaic cell. The back substrate is disposed on the moisture absorbing layer. The sealant is disposed between the front substrate and the back substrate and is positioned at or near the edges of the front substrate and the back substrate. The sealant substantially seals the photovoltaic cell and the moisture absorbing layer therein.

In one embodiment of the disclosure, the photovoltaic panel optionally includes an encapsulant disposed between the cell and the moisture absorbing layer to encapsulate the cell.

In another embodiment of the disclosure, the photovoltaic panel optionally includes an encapsulant disposed between the moisture absorbing layer and the back substrate to encapsulate the cell.

In a further embodiment of the disclosure, the moisture absorbing layer optionally includes a micro-porous desiccant structured as a molecular sieve. The pore size of the micro-porous desiccant ranges from about 0.3 nm to about 1 nm, and the micro-porous desiccant includes zeolite.

In yet another embodiment of the disclosure, the moisture absorbing layer optionally includes an encapsulant and a micro-porous desiccant blended in the encapsulant. The micro-porous desiccant includes zeolite, and the encapsulant includes ethyl vinyl acetate.

According to another aspect of the disclosure, a method of manufacturing a photovoltaic panel is provided. The method includes the following steps: forming a photovoltaic cell on a front substrate; applying a moisture absorbing layer covering the photovoltaic cell; applying a sealant at or near the edges of the front substrate; and securing a back substrate to the front substrate such that the photovoltaic cell and the moisture absorbing layer are situated within an enclosed space formed by the front substrate, the back substrate and the sealant.

In one embodiment of the disclosure, the step of applying the moisture absorbing layer optionally includes a step of laminating a film of a micro-porous desiccant onto the cell. The micro-porous desiccant includes a getter composite film containing zeolite nanoparticles.

In another embodiment of the disclosure, the step of applying the moisture absorbing layer optionally includes a step of laminating a film of an encapsulant and a micro-porous desiccant blended in the encapsulant onto the cell. The encapsulant includes ethyl vinyl acetate, and the micro-porous desiccant includes zeolite.

In the foregoing, the photovoltaic cell in the photovoltaic panel is protected not only by the sealant but also by the moisture absorbing layer. By trapping the water molecules of the moisture in the moisture absorbing layer, the moisture intrusion into the photovoltaic cell is prevented, and the power degradation of the photovoltaic cell is avoided.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiments, with reference made to the accompanying drawings as follows:

FIG. 1 is a cross-sectional view of a photovoltaic panel according to one embodiment of the disclosure;

FIG. 2 is a cross-sectional view of a photovoltaic panel according to another embodiment of the disclosure;

FIG. 3 is a cross-sectional view of a photovoltaic panel according to a further embodiment of the disclosure; and

FIG. 4 is a flow chart of a method of manufacturing a photovoltaic panel according to one embodiment of the disclosure.

### DETAILED DESCRIPTION

The photovoltaic panel and the method of manufacturing the photovoltaic panel utilize a moisture absorbing layer to trap moisture and pollutant gases. The problems of material delamination, erosion, and power degradation of the is panel can therefore be prevented. Thus the life span of the panel is extended.

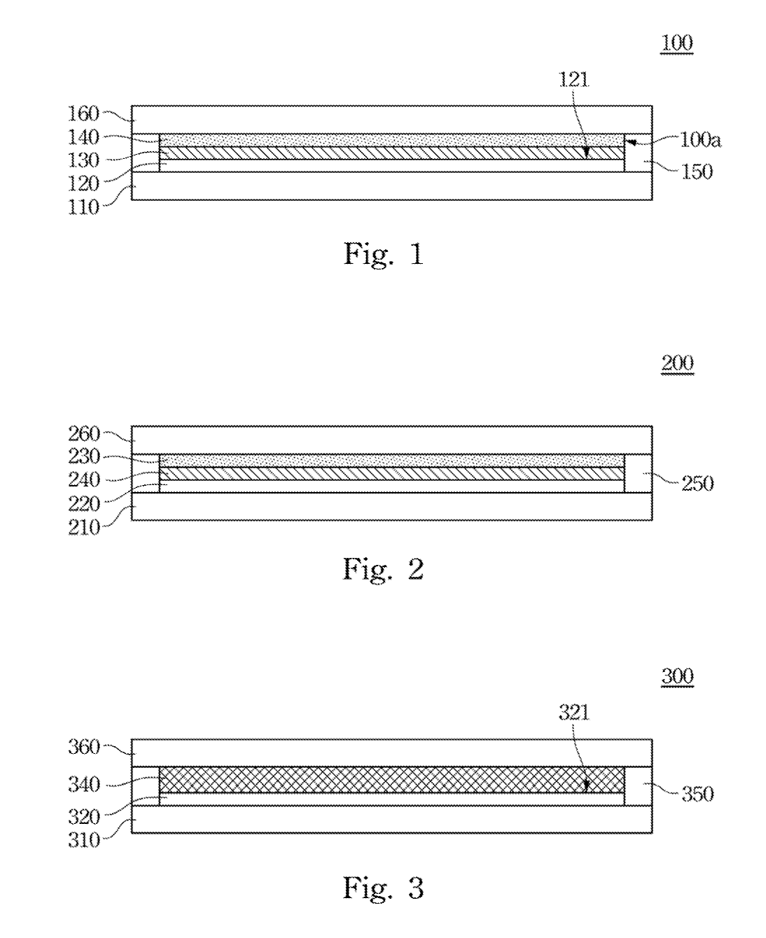

FIG. 1 is a cross-sectional view of a photovoltaic panel according to one embodiment of the disclosure. The photovoltaic panel 100 includes a front . substrate 110, a photovoltaic cell 120, a moisture absorbing layer 140 and a back substrate 160. The photovoltaic cell 120 is disposed on the front substrate 110, and the moisture absorbing layer 140 covers the photovoltaic cell 120. The back substrate 160 is parallel to the front substrate 110, and the photovoltaic cell 120 and the moisture absorbing layer 140 are situated between the front substrate 110 and the back substrate 160.

In one embodiment, the material of the front substrate 110 is exemplified by a transparent conductive oxide (TCO) glass. However, the front substrate 110 is not limited to the TCO glass. Alternatively, the front substrate 110 can also be made of appropriate polymer films, such as DuPont™ Teflon® films, DuPont™ Teonex® polyethylene naphthalate (PEN) films and DuPont™ Melinex® ST polyester films. Practically, any other appropriate materials that are of high transmittance, light weighted, flexible, good UV resistance, and/or sufficient mechanical strength can be used in manufacturing the photovoltaic panel 100 of the present disclosure.

On the other hand, the photovoltaic cell 120 is exemplified by a thin film photovoltaic cell having multiple metal layers deposited on the front substrate 110. Exemplary materials of the metal layers include, but are not limited to, amorphous silicon, cadmium diselenide (CdS), cadmium telluride (Cd/Te), copper indium diselenide (CIS), and/or copper indium gallium diselenide (CIGS). The photovoltaic cell 120 may be deposited by known depositing methods, such as chemical vapor deposition (CVD), physical vapor deposition (PVD), sputtering, or any other methods known to a person skilled in the art.

In the present embodiment, the moisture absorbing layer 140 includes a micro-porous desiccant structured as a molecular sieve. The micro-porous desiccant includes zeolite that is a crystalline aluminosilicate material serving as the molecular sieve to trap moisture and even pollutant gases like nitride compounds. The pore size of the micro-porous desiccant ranges from about 0.3 nm to about 1 nm, so as to trap water molecules and other molecules harmful to the photovoltaic cell 120. Practically, the pore size of the micro-porous desiccant can be 0.3, 0.4, 0.5, 0.6, 0.7, 0.8, 0.9 or 1.0 nm.

Although the moisture absorbing layer 140 is exemplified by including zeolite in the present embodiment, it is not limited thereto. Other crystalline materials having uniform molecular-scale pores to form a molecular sieve and to separate molecules based on sizes, shapes and polarities, may be used in the photovoltaic panel 100 of the present embodiment.

As shown in FIG. 1, the moisture absorbing layer 140 covers the photovoltaic cell 120. More specifically, the moisture absorbing layer 140 overlays a top surface 121 of the photovoltaic cell 120, such that the moisture penetrating through the back substrate 160 can be trapped by the moisture absorbing layer 140. In this manner, the photovoltaic cell 120 is protected from the moisture intrusion. The problems of moisture penetrating through the back substrate 160 can be prevented, therefore would increase the life span of the photovoltaic panel 100.

In addition to the above described front substrate 110, photovoltaic cell 120, moisture absorbing layer 140 and back substrate 160, the photovoltaic panel 100 of the present embodiment further includes an encapsulant 130 and a sealant 150. In one embodiment, the encapsulant 130 is disposed between the photovoltaic cell 120 and the moisture absorbing layer 140 to encapsulate the photovoltaic cell 120. The sealant 150 is disposed between the front substrate 110 and the back substrate 160, and is positioned at or near the edges of the front substrate 110 and the back substrate 160 so as to seal the photovoltaic cell 120 and the moisture absorbing layer 140 therein. More specifically, the sealant 150 is exemplified by disposing in a margin area of the front substrate 110 outside the photovoltaic cell 120, the encapsulant 130 and the moisture absorbing layer 140. In this manner, the sealant 150 completely seals the photovoltaic panel 100 and forms an enclosed space 100a with the front substrate 110 and the back substrate 160. The photovoltaic cell 120 and the moisture absorbing layer 140 are situated in the enclosed space 100a to be protected from moisture and/or pollutant intrusion.

In the photovoltaic panel 100 as shown in FIG. 1, the materials of the encapsulant 130 and the sealant 150 can be selected in accordance with the practical production needs. The exemplary materials for the encapsulant 130 includes, for example, commercially obtainable DuPont™ Elvax® ethyl vinyl acetate (EVA) resins, commercially obtainable DuPont™ PV5200 series encapsulant sheets, and commercially obtainable DuPont™ PV5300 series encapsulant sheets. The exemplary materials for the sealant 150 includes, for example, polyisobutylene (PIB), butyl rubber, VAMAC™, ethylene acrylic elastomers, Hypalon™, and chlorosulfonated polyethylene. The above mentioned materials are for exemplifications only, and are not intended to limit the scope of the disclosure.

In the present embodiment of FIG. 1, the encapsulant 130 is exemplified is by disposing between the photovoltaic cell 120 and the moisture absorbing layer 140, yet the disposition of the encapsulant 130 it is not limited thereto. FIG. 2 is a cross-sectional view of a photovoltaic panel according to another embodiment of the disclosure. The photovoltaic panel 200, including the front substrate 210, the photovoltaic cell 220, the encapsulant 230, the moisture absorbing layer 240, the sealant 250, and the back substrate 260, differs from the photovoltaic panel 100 of FIG. 1 in that the encapsulant 230 is disposed between the moisture absorbing layer 240 and the back substrate 260 to encapsulate the photovoltaic cell 220. Any other appropriate dispositions of the encapsulant to fully cover the photovoltaic cell can be used in the photovoltaic panel.

As shown in FIG. 1, the encapsulant 130 and the moisture absorbing layer 140 are illustrated as two different layers, so are the encapsulant 230 and the moisture absorbing layer 240 depicted in FIG. 2. However, in another embodiment, the two separate layers can be combined into one layer.

FIG. 3 is a cross-sectional view of a photovoltaic panel according to a further embodiment of the disclosure. The photovoltaic panel 300 includes a front substrate 310, a photovoltaic cell 320, a moisture absorbing layer 340, a sealant 350 and a back substrate 360. The photovoltaic cell 320 is disposed on the front substrate 310, and the moisture absorbing layer 340 covers the photovoltaic cell 320. The back substrate 360 is parallel to the front substrate 310, and the photovoltaic cell 320 and the moisture absorbing layer 340 are situated between the front substrate 310 and the back substrate 360. The moisture absorbing layer 340 covers the photovoltaic cell 320, more specifically, fully overlays a top surface 321 of the photovoltaic cell 320.

The moisture absorbing layer 340 of the present embodiment includes an encapsulant and a micro-porous desiccant blended in the encapsulant. The micro-porous desiccant is structured as a molecular sieve and includes zeolite, which is similar to that included in the moisture absorbing layer 140 of the previously described photovoltaic panel 100 (as depicted in FIG. 1). The micro-porous desiccant is blended in the encapsulant by mixing a predetermined proportion of zeolite nanoparticles into the encapsulant raw material, e.g. EVA resin, during the formation of the EVA film. The micro-porous desiccant serves as a molecular sieve to trap moisture and pollutant gases. The pore size of the micro-porous desiccant ranges from about 0.3 nm to about 1 nm. On the other hand, the exemplary materials for the encapsulant includes, for example, commercially obtainable DuPont™ Elvax® ethyl vinyl acetate (EVA) resins, commercially obtainable DuPont™ PV5200 series encapsulant sheets, and commercially obtainable DuPont™ PV5300 series encapsulant sheets.

The photovoltaic panel 300 uses one layer of encapsulant with micro-porous desiccant blended therein, to encapsulate the photovoltaic cell 320 and to trap moisture at the same time, thus the structure of the photovoltaic panel 300 is further simplified and the cost is reduced accordingly.

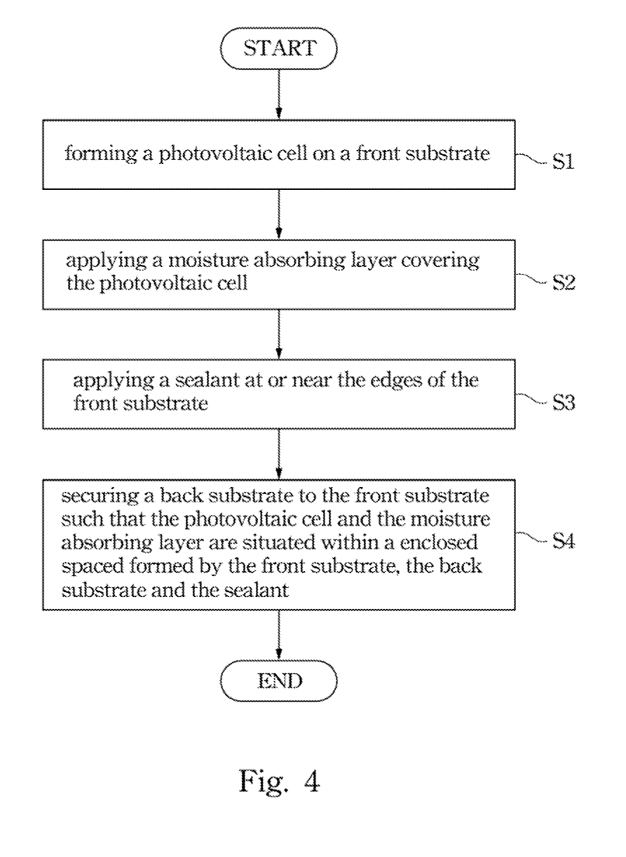

The detailed description now directs to a method of manufacturing a photovoltaic panel. In order to clearly show the characteristics of the disclosure, the above mentioned photovoltaic panel 100 is taken as an example here with reference to FIG. 1 and FIG. 4. FIG. 4 is a flow chart of a method of manufacturing a photovoltaic panel according to one embodiment of the disclosure.

Of the method of manufacturing the photovoltaic panel 100, the photovoltaic cell 120 is formed on the front substrate 110 as shown in step S1. The photovoltaic cell 120 may be deposited by chemical vapor deposition (CVD), physical vapor deposition (PVD), sputtering, or any other methods known to a person who is skilled in the art.

In step S2, the moisture absorbing layer 140 is applied to cover the photovoltaic cell 120. Exemplarily, the step S2 is performed by laminating a film of the micro-porous desiccant, zeolite for example, onto the photovoltaic cell 120. For example, a getter composite film containing zeolite nanoparticles can be laminated onto the photovoltaic cell 120.

Optionally, a step of encapsulating the photovoltaic cell 120 by the encapsulant 130 can be performed prior to laminating the film. Alternatively, the step of encapsulating the photovoltaic cell 120 is performed after step S2 in another embodiment. The sequence of the two steps is not limited here in the disclosure, as long as the photovoltaic cell 120 can be encapsulated by the encapsulant 130 and covered by the moisture absorbing layer 140.

In another embodiment, the step S2 and the step of encapsulating the photovoltaic cell 120 can be combined into one step by laminating a film of the encapsulant with the micro-porous desiccant blended therein. The photovoltaic cell 120 is therefore protected from the intrusion of moisture and pollutants by the laminated film. The micro-porous desiccant can be exemplified by zeolite, and the encapsulant can be exemplified by EVA. The micro-porous desiccant is formed by mixing a predetermined proportion of zeolite nanoparticles into the encapsulant raw material, e.g. EVA resin, during the formation of the EVA film. Then, the encapsulant is laminated over the photovoltaic cell 120.

Then, the method moves on to step S3, in which the sealant 150 is applied at or near the edges of the front substrate 110. In one embodiment, the sealant 150 is applied to a marginal area of the front substrate 110 outside the photovoltaic cell 120, the encapsulant 130 and the moisture absorbing layer 140. More specifically, the sealant 150 is disposed completely surrounding the photovoltaic cell 120, the encapsulant 130 and the moisture absorbing layer 140.

Finally, in step S4, the back substrate 160 is secured onto the front substrate 110. As a result, the photovoltaic cell 120, the moisture absorbing layer 140 and the sealant 150 are situated within a space formed by the front substrate 110, the back substrate 160 and the sealant 150. Specifically, the sealant 150, the front substrate 110 and the back substrate 160 form an enclosed space 100a, and the photovoltaic cell 120 and the moisture absorbing layer 140 are enclosed therein or are situated in the enclosed space 100a.

After completion of step S4, the photovoltaic panel 100 is thereby completed. By the protection of the sealant 150 and the moisture absorbing layer 140, the moisture intrusion to the photovoltaic cell 120 is prevented, as well as the delamination and corrosion of materials in the photovoltaic panel 100.

In the above-described photovoltaic panel and method of manufacturing the same, the moisture intrusion from the back substrate of the panel can be blocked by the moisture absorbing layer, so as to prevent the delaminations and corrosions of materials and to prolong the life span of the photovoltaic panel accordingly. Furthermore, the power degradation of the photovoltaic cell is prevented, increasing the reliability and the performance of the photovoltaic panel. Moreover, the moisture absorbing layer includes zeolite or encapsulant with zeolite blended therein, making the moisture absorbing layer cheap and easy to obtain.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A photovoltaic panel, comprising:
a front substrate;
a photovoltaic cell disposed on the front substrate;
a moisture absorbing layer covering the photovoltaic cell;
a back substrate disposed on the moisture absorbing layer; and
a sealant disposed between the front substrate and the back substrate and positioned at or near the edges of the front substrate and the back substrate, wherein the sealant substantially seals the photovoltaic cell and the moisture absorbing layer therein.

2. The photovoltaic panel of claim 1 further comprising:
an encapsulant disposed between the photovoltaic cell and the moisture absorbing layer to encapsulate the photovoltaic cell.

3. The photovoltaic panel of claim 1 further comprising:
an encapsulant disposed between the moisture absorbing layer and the back substrate to encapsulate the photovoltaic cell.

4. The photovoltaic cell of claim 1, wherein the moisture absorbing layer comprises a micro-porous desiccant structured as a molecular sieve.

5. The photovoltaic panel of claim 4, wherein the pore size of the micro-porous desiccant ranges from about 0.3 nm to about 1 nm.

6. The photovoltaic panel of claim 4, wherein the micro-porous desiccant comprises zeolite.

7. The photovoltaic panel of claim 1, wherein the moisture absorbing layer comprises an encapsulant and a micro-porous desiccant blended in the encapsulant.

8. The photovoltaic panel of claim 7, wherein the micro-porous desiccant comprises zeolite.

9. The photovoltaic panel of claim 7, wherein the encapsulant comprises ethyl vinyl acetate.

10. The photovoltaic panel of claim 1, wherein the front substrate, the sealant and the back substrate form an enclosed space, and the photovoltaic cell and the moisture absorbing layer are situated in the enclosed space.

11. A method of manufacturing a photovoltaic panel, comprising:
forming a photovoltaic cell on a front substrate;
applying a moisture absorbing layer to cover the photovoltaic cell;
applying a sealant at or near the edges of the front substrate; and
securing a back substrate to the front substrate such that the photovoltaic cell and the moisture absorbing layer are situated within an enclosed space formed by the front substrate, the back substrate and the sealant.

12. The method of claim 11, wherein the step of applying the moisture absorbing layer comprises:
laminating a film of a micro-porous desiccant onto the photovoltaic cell.

13. The method of claim 12, wherein the micro-porous desiccant comprises a getter composite film containing zeolite nanoparticles.

14. The method of claim 12, wherein the step of applying the moisture absorbing layer comprises:
laminating a film of an encapsulant and a micro-porous desiccant blended in the encapsulant onto the photovoltaic cell.

15. The method of claim 14, wherein the encapsulant comprises ethyl vinyl acetate.

16. The method of claim 14, wherein the micro-porous desiccant includes zeolite.

17. The method of claim 12 further comprising:
encapsulating the photovoltaic cell by an encapsulant.
